(19) United States
(12) Patent Application Publication
(10) Pub. No.: US 2021/0408888 A1
(43) Pub. Date: Dec. 30, 2021

(54) ROTOR WITH SUPERCONDUCTING WINDING FOR CONTINUOUS CURRENT MODE OPERATION

(71) Applicant: SIEMENS AKTIENGESELLSCHAFT, München (DE)

(72) Inventors: Jörn Grundmann, Grossenseebach (DE); Marijn Pieter Oomen, Erlangen (DE); Peter Van Hasselt, Erlangen (DE)

(21) Appl. No.: 17/269,368

(22) PCT Filed: Aug. 20, 2019
(86) PCT No.: PCT/EP2019/072198

§ 371 Date: Jul. 9, 2021

(30) Foreign Application Priority Data
Aug. 21, 2018 (DE) 10 2018 214 049.9
Sep. 19, 2018 (DE) 10 2018 215 917.3

(51) Int. Cl. H02K 55/04

(52) U.S. Cl. CPC H02K 55/04

(57) ABSTRACT

A rotor for an electrical machine is disclosed herein. The rotor includes a rotor housing, a winding carrier arranged therein, at least one first axial connecting element mechanically interconnecting the winding carrier and the rotor housing, and a superconducting rotor winding configured to produce a magnetic field. The rotor winding is mechanically retained by the winding carrier and is part of a self-contained circuit inside the rotor in which circuit a continuous current may flow. The self-contained circuit has a continuous current switch with a switchable conductor section that may be switched between a superconducting state and a normally conducting state. The switchable conductor section is arranged on the first axial connecting element. A machine including the rotor and a method for operating the rotor is also disclosed herein.

The present patent document is a § 371 nationalization of PCT Application Serial No. PCT/EP2019/072198, filed Aug. 20, 2019, designating the United States, which is hereby incorporated by reference, and this patent document also claims the benefit of German Patent Application No. 10 2018 214 049.9, filed Aug. 21, 2018, and German Patent Application No. 10 2018 215 917.3, filed Sep. 19, 2018, which are also hereby incorporated by reference.

### TECHNICAL FIELD

The present disclosure relates to a rotor for an electrical machine having a superconducting rotor winding, wherein the superconducting rotor winding is part of a self-contained circuit in which a continuous current is configured to flow. The closed circuit has a continuous current switch having a switchable conductor section which may be switched between a superconducting state and a normally conducting state. The disclosure furthermore relates to an electrical machine having such a rotor and a method for operating such a rotor.

### BACKGROUND

According to the prior art, electrical machines are frequently equipped with a rotor winding to generate the rotor field. The power ranges which may be covered hereby may be greater than for machines excited by permanent magnets. For field generation, an electric current has to flow through such a rotor winding. This current may be supplied by a current source, which is arranged in a stationary manner (e.g., outside the rotating system of the rotor). This solution is disadvantageous in that, in this case, a comparatively sophisticated transmission device is required to transmit the current from the stationary system to the rotating rotor winding. In this case, for example, either solutions based on collector rings or solutions based on so-called exciters may be used. However, both variants are comparatively complex, and each require at least one option for supplying the exciting current which is in permanent use during the operation of the electrical machine. The current source and the transmission device for the current each contribute to the weight and to the volume of the electrical machine.

In the case of a conventional rotor winding, this includes a resistive conductor material, (e.g., copper or aluminum). Such a conductor material results in corresponding ohmic losses which, depending on the machine size, may be in the range of several kilowatts to megawatts. To prevent these losses, machines are also alternatively known whereof the rotor winding includes a superconducting conductor material. Such a material transports the current in a virtually lossless manner in the superconducting operating state (e.g., at an operating temperature below the transition temperature of the superconductor) and therefore prevents the above-mentioned ohmic losses. The efficiency of the electrical machine is thus increased accordingly. Moreover, owing to the loss-free current transport, it is possible to achieve higher operating currents and therefore higher fields. Compared to a conventional machine, a superconducting machine may thus be built smaller and lighter with the same power, which also leads to an increase in the power density.

Also, in the case of the most commonly known superconducting rotor windings, these are permanently connected to an exciter during the operation of the machine, which, as described above, may include a stationary current source and a transmission device for transmitting the current to the rotating winding. However, this additional weight contribution is disadvantageous for developing an electrical machine with a very high-power density. In particular, when such a machine is used in a vehicle (in particular in an aircraft), it would be advantageous to be able to further reduce the weight of the machine while maintaining the same power.

German patent application 10 2017 219 384 A1 describes a rotor having a superconducting rotor winding for forming a p-pole magnetic field, wherein the rotor winding is provided to operate in a continuous current mode and forms a self-contained circuit for this purpose. In the case of this rotor, after an operating current has been supplied, it is therefore possible to disconnect the rotor winding from the current source used, wherein a virtually constant current remains in the closed circuit of the rotor winding after the disconnection. To enable the supply of the current, the closed circuit has a switchable conductor region, which may be switched between a superconducting state and a normally conducting state. In the application, a sub-region of the rotor winding is provided for this purpose, in particular a winding section, which may correspond either to precisely one magnetic pole or to a plurality of magnetic poles.

However, the solution described therein is disadvantageous in that a significant part of the rotor winding has to be heated to open the continuous current switch. Therefore, a large amount of heat is generated in the region of the rotor winding, which firstly has to be dissipated again prior to use in the superconducting continuous current mode. Moreover, as a result of the local heating, thermal gradients are produced in the coil which may lead to damage of the superconductor as a result of the associated mechanical stresses. All in all, an undesired asymmetry in the construction of the rotor winding is generated as a result of using a specific winding section as a switch. A further disadvantage of using one or more magnetic poles as a switch includes that the supply current only flows in the remaining poles of the winding during the power supply procedure and the magnetic energy has to be distributed to all poles after the termination of the power supply. To still achieve the specified operating current in the continuous current mode, a supply current, which is selected to be correspondingly higher, is used during the power supply process. This leads to an undesirably high current load on all components during the power supply procedure.

### SUMMARY AND DESCRIPTION

The object of the disclosure is therefore to specify a rotor for an electrical machine which overcomes the disadvantages. The aim is to provide a rotor in which a continuous current may be supplied to the rotor winding. In this case, in particular, the heat input into the rotor winding during the power supply process may be kept as low as possible. Furthermore, the symmetry of the rotor winding may be disrupted as little as possible and/or the current required during the power supply process may be kept as low as possible. A further object is to provide an electrical machine having such a rotor. In addition, the aim is also to provide a method for operating such a rotor.

These objects are achieved by the rotor, machine, and method described herein. The scope of the present disclosure is defined solely by the appended claims and is not affected to any degree by the statements within this summary. The present embodiments may obviate one or more of the drawbacks or limitations in the related art.

The rotor is configured as a rotor for an electrical machine. The rotor includes a rotor outer housing, a winding carrier arranged therein, and at least a first axial connecting element, which mechanically connects the winding carrier and the rotor outer housing to one another. The rotor furthermore includes a superconducting rotor winding, which is configured to form a magnetic field, wherein the rotor winding has one or more superconducting coil elements which are mechanically held by the winding carrier. In this case, the superconducting rotor winding is part of a self-contained circuit, which is arranged within the rotor and in which a continuous current may flow. This closed circuit has a continuous current switch having a switchable conductor section which may be switched between a superconducting state and a normally conducting state. The switchable conductor section is arranged on the first axial connecting element.

The continuous current does not necessarily have to be an extremely constant current here, such as that required, for example, for the so-called continuous current mode of a superconducting magnet in a magnetic resonance device (MR magnet). In particular, it is therefore not required that the value of the continuously flowing current remains constant over hours, days or even weeks with an extremely small decay (for example, maximally in the per mil range in the case of MR magnets). An important factor for a continuous current in association is that a current flow which does not alter in terms of its order of magnitude is maintained at least over a time period of several hours. In this case, a decay of the current by approximately 10% to 20% of its original value is totally acceptable for operating the machine. In the sense in which the term “continuous current” is used here, this may also refer to a pseudo continuous current.

In principle, the switching of the switchable conductor section between the superconducting state and the normally conducting state may take place in different ways. In this regard, such a switching may take place, for example, as a result of a local heating (similarly to the conventional supply of current in magnetic resonance magnets) or as a result of magnetically triggered quenching.

The described arrangement of the switchable conductor section “on” the first axial connecting element may mean that the conductor section is mechanically held by this connecting element. However, it is not absolutely necessary for the conductor section and the connecting element to be in direct contact with one another for this purpose. It is, for example, also possible for the conductor section to be connected to the connecting element via an additional supporting element.

An advantage of the rotor includes that the supply of current to the closed circuit of the rotor winding is enabled by the switchable conductor section without the rotor winding itself thereby being substantially altered in comparison to a conventional rotor winding. In particular, the switchable conductor section here is not realized as a component part of a superconducting coil element of the rotor winding, but as an element which is separate from the rotor winding. As a result of its arrangement on the first axial connecting element, the switchable conductor section is spatially separated from the rotor winding. The superconducting coil elements of the rotor winding are namely supported by the winding carrier. On the other hand, the axial connecting element is expediently arranged axially adjacent to this winding carrier. The switchable conductor section is thus located in an axial position on the rotor which differs from that of the rotor winding. This axial spacing also results, in particular, in a thermal separation of the switchable conductor section from the superconducting coil elements of the rotor winding. The consequence of this spatial and thermal separation is that the heating of the switchable conductor section which may occur when the continuous current switch is opened only results in a slight heating of the superconducting coil elements of the rotor winding. Such heating is minimized so that, in contrast to the continuous current switch, these coil elements remain in the superconducting state. An undesired heat input into the rotor winding during the power supply procedure may therefore be advantageously reduced as a result of the separate arrangement.

A further advantage of the described spatial separation of the switchable conductor section and the rotor winding may be seen in that the rotor winding may be constructed as a substantially rotationally symmetrical winding and the symmetry is not disrupted by the continuous current switch. In particular, such a rotational symmetry is not disrupted as a result of certain sub-regions of the winding for the function as a continuous current-switch needing to be configured differently from the remaining part of the winding.

A further advantage of the described spatial separation of the switchable conductor section and the rotor winding may be seen in that an electromagnetic interaction between the switchable conductor section and the rotor winding may be kept advantageously small. As a result, undesired magnetic influences of the continuous current switch on the magnetic field of the rotor winding may be reduced on the one hand. On the other, mechanical loads within the rotor, which might be produced as a result of these undesired magnetic interactions, may be reduced.

The arrangement of the switchable conductor section on the first axial connecting element is particularly advantageous because the temperature level in the region of such a connecting element may be between the cryogenic operating temperature of the rotor winding and the warm external ambient temperature. Such a temperature level is also referred to below as “intermediate temperature”. The winding carrier and the superconducting coil elements of the rotor winding may be at a cryogenic temperature, which is considerably lower than the transition temperature of the superconducting material of this winding. The rotor outer housing, on the other hand, may be at a comparatively warm temperature. The connecting element arranged between these two elements therefore has a temperature gradient and, in particular, has a region with an intermediate temperature. A region with such an intermediate temperature is particularly suitable for the continuous current switch in order to enable a thermal switching between a closed and an open state of the switch here. It is furthermore favorable if the heat produced when the switch is opened is not released in the cryogenic region of the rotor winding but in a region with such an intermediate temperature. The reason is that more efficient cooling may be realized for an element with such an intermediate temperature than for the colder regions of the rotor. The energy losses caused by the cooling may therefore be reduced as a result of this arrangement.

The electrical machine has a rotor and a stator arranged in a stationary manner. The advantages of this machine are revealed analogously to the advantages described above for the rotor.

The method for operating a rotor includes: connecting the rotor winding to an external current source via two connecting nodes, which are arranged within the closed circuit, in each case adjacent to the switchable conductor section; subsequently supplying a current to the rotor winding by the external current source; and subsequently disconnecting the rotor winding from the external current source.

The advantageous of the method are also revealed analogously to the advantages described above for the rotor. In general, it is the case that the external current source is not part of the described closed circuit. The supply of the current takes place in particular to the part of the closed circuit which is not realized by the switchable conductor section but by the rotor winding. The supply of the current from the current source to the rotor winding may take place in particular when the switchable conductor section is in a normally conducting state. All in all, as a result of the connecting of the rotor winding, the supplying of the current, and the disconnecting of the rotor winding, a current is supplied to the rotor winding which continues to flow through the rotor winding as a continuous current after the disconnection from the external current source. This maintaining of the continuous current takes place, in particular, when the switchable conductor section has been switched to a superconducting state again following the supply of current.

The acts may be advantageously carried out in the sequence. In this case, the following additional act may optionally take place between the connecting of the rotor winding and the supplying of the current: opening the continuous current switch.

This may take place, for example, by heating the switchable conductor section.

Furthermore, at least one of the following acts may optionally take place between the supplying of the current and the disconnecting of the rotor winding: closing the continuous current switch; and/or bringing the current supplied by the external current source down to 0 A.

Advantageous configurations and developments of the disclosure are revealed in the claims and in the description below. In this case, the described configurations of the rotor, the electrical machine, and the operating method may be advantageously combined with one another.

In an advantageous manner, the rotor may additionally include a second axial connecting element, which mechanically connects the winding carrier and the rotor outer housing to one another on a side opposite the first axial connecting element. This is expedient in order to mechanically support the winding carrier, with the rotor winding held thereon, axially on both sides. This in turn contributes to an increase in the mechanical stability during the rotation of the rotor and, in particular, to an increase in the running smoothness. In this case, the bulk of the torque to be transmitted may be transmitted to one of these two axial sides. This side is frequently referred to among experts as the drive side or A side. Accordingly, the opposite side is frequently referred to as the operating side or B side. On the B side, the axial connecting element present there may also be designed for a torque-locked connection between the winding carrier and the rotor outer housing. The amount of torque transmitted on the B side may be considerably lower than the amount of torque transmitted on the A side because the rotor outer housing may be connected to a drive shaft of the electrical machine on the A side.

In the embodiments in which the rotor has two such axially opposed connecting elements, the continuous current switch is expediently arranged on only one of these two connecting elements. This may be either a connecting element on the A side or a connecting element on the B side. Irrespective of the precise arrangement, it is in any case favorable if the continuous current switch is on the same axial side of the rotor as that on which the current feeds for connecting the superconducting rotor to an external circuit are also present. In an expedient manner, the rotor may have two such current feeds. These current feeds may likewise be particularly advantageously routed at least partially on the first axial connecting element. The current feeds may thus be connected in a relatively simple manner to the continuous current switch present there. Each of the current feeds expediently has an axially outer normally conducting conductor section and an axially inner superconducting conductor section. Each of the current feeds has a node point between these two conductor sections connected in series to one another. These two node points may be advantageously connected to one another by the described continuous current switch.

The continuous current switch is advantageously held at an intermediate temperature during operation, as described above. The two normally conducting conductor sections of the current feeds are expediently routed on the comparatively warmer, axially further outward lying part of the first connecting element. Conversely, the two superconducting conductor sections of the current feeds are routed on the comparatively colder, axially further inward lying part of the first connecting element. In other words, as a result of the described arrangement of the continuous current switch and the individual sections of the current feeds, the axial temperature gradient—present in any case—of the first connecting element is advantageously used to provide expedient operating temperatures for the individual components in each case.

The switchable conductor section may be a linear conductor section, which extends, for example, in the axial direction of the rotor. This linear conductor section may be arranged co-linearly to the first connecting element on one of its outer surfaces. In the case of a simple implementation of this type, with a simple linear conductor, the maximum length of the switchable conductor section is determined substantially by the axial length of the connecting element.

However, it may sometimes be desirable to design the switchable conductor section with a longer conductor length. Therefore, according to an alternative embodiment, it may be advantageous if the switchable conductor section has at least one switchable coil element. In other words, the switchable conductor section in this case may have one or more coil windings so that the total length of this conductor section may also be selected to be longer than the axial length of the connecting element which supports it. A comparatively long conductor length for the switchable conductor section may be advantageous, for example, in order to be able to achieve a required minimum resistance of the continuous current switch in its open state.

In principle, different coil forms are possible in the case of the described switchable coil element. With a higher winding count, it may be possible to achieve a longer total length of the switchable conductor section. According to an embodiment, such a switchable coil element may be designed in particular as a flat coil. This is particularly expedient when a flat superconducting strip conductor material is used. The winding axis of such a flat coil may be arranged coaxially to the central axis A of the rotor, for example. In particular, such a flat coil may be arranged radially externally around a cylindrical axial connecting element. Both the flat coil and the cylindrical connecting element may advantageously have a substantially circular cross-section.

The embodiment of the continuous current switch may not be restricted to having one such coil element. In this regard, it is also possible, in particular, that the continuous current switch is composed of a plurality of coil elements. In this case, a plurality of coil elements may be connected in series. This may be advantageous in order to achieve a required minimum resistance in the open state of the switch, for example. Alternatively or additionally, a plurality of coil elements may also be connected in parallel. This may be advantageous for enabling the operating current of the rotor to be carried in a sufficiently loss-free manner at the operating temperature of the continuous current switch. In this case, it may also be possible for the here-described series connection or parallel connection of a plurality of conductor elements to be realized analogously for a plurality of simple conductor elements (which are not present in coil form). Alternatively to the described flat coils, other coil forms may also be used, (e.g., one or more helically formed coils), which may be wound around an outer surface of a cylindrical connecting element.

According to an embodiment, the switchable coil element of the continuous current switch may be configured as a bifilar wound coil element. A bifilar coil winding is understood here to mean a winding including two conductor branches, in which the total inductance of the coil is substantially reduced as a result of the current flowing in opposite directions in the two conductor branches. In this case, the two conductor branches do not necessarily have to be present as separate conductor elements. Instead, the two conductor branches may be present as parts of a continuous entire conductor, wherein the current flow in opposite directions may be achieved by providing a reversal point. Such a reversal point may be realized, for example, on the radially outer side or the radially inner side of a bifilar flat coil. The reversal point may also be a location at which the two separate conductor branches are connected to one another by a contact piece.

An advantage of such a bifilar coil arrangement in the continuous current switch includes that, despite a longer conductor length and a correspondingly high resistance in the open state, a comparatively low inductance of the switch may be achieved. Such a low inductance is desirable so that, on the one hand, an undesired electromagnetic influence of the continuous current switch on the rotor winding is prevented. On the other hand, the undesired mechanical loads which may occur as secondary ancillary effects of such an electromagnetic interaction between the rotor winding and the continuous current switch may be prevented.

Alternatively to the described bifilar individual winding, two separate flat coils may also be arranged closely axially adjacent to one another and may therefore be electrically connected to one another in series such that the direction of rotation is in turn contrary to the current flow direction in these two mutually adjacent flat coils and the inductances of the two individual coils substantially cancel each other out. A “bifilar coil pair” may thus be formed, in which the total inductance in comparison to the two individual coils is likewise advantageously reduced.

According to an embodiment, the first axial connecting element may have, in particular, a tubular design. For example, such a connecting element may be configured as a hollow cylindrical element, in particular, with a circular cross-section. Such a connecting tube may be advantageous for also transmitting a high torque with a comparatively small material cross-section. This is particularly advantageous in the case of comparatively large tube diameters. In this regard, for example, the outer diameter of such a tubular connecting element may be 100 mm or more.

A comparatively small material cross-section of such a connecting element may be advantageous for keeping the axial heat conduction via the connecting element as low as possible. The axial heat conduction may be as low as possible here in order to enable efficient cooling of the axially inner parts of the rotor. Because a cryogenic operating temperature is required in the region of the superconducting rotor winding, any heat input in this region leads to a high cooling effort and to high energy losses.

A tubular configuration of the connecting element has the further advantage that the interior of this tube may be used to introduce a fluid coolant into the inner regions of the rotor (and accordingly also to discharge it again). Such a fluid coolant may circulate, for example, in the interior of the rotor according to the thermosiphon principle. To this end, for example, either the connecting element may be used directly as a thermosiphon tube or one or more additional tubes may be routed in the interior of the connecting tube.

However, alternatively to the described tubular configurations, it is also possible that the first axial connecting element is configured as a solid connecting element.

In an advantageous manner and irrespective of the precise configuration of the switchable conductor section and the axial connecting element, the switchable conductor section may be configured to be substantially rotationally symmetrical and may be arranged on the axial connecting element such that it is coaxial thereto. This has the advantage that a substantial unbalance is not generated by the switchable conductor section during the rotation of the rotor.

According to a first advantageous embodiment variant, the first axial connecting element may be arranged on the drive side of the rotor relative to the winding carrier. In this embodiment, therefore, in particular both the continuous current switch and the current feeds may be provided on that side on which the substantial proportion of the torque is also transmitted between the winding carrier and the rotor shaft. The corresponding connecting element may be formed from a mechanically solid material on this drive side so that current feeds and continuous current switches may likewise be held without difficulty in a mechanically fixed manner. The diameter of the connecting element may be sufficiently large on this side so that, in particular, a switchable coil element with suitable dimensions may also be arranged on its outer surface.

According to an alternative advantageous embodiment variant, the first axial connecting element may be arranged on the operating side of the rotor relative to the winding carrier. Very high torques do not have to be transmitted on this side and a relatively high design freedom is provided accordingly for the corresponding connecting element. In particular, the material of the connecting element and the material cross-section thereof may be selected such that only a very low heat input into the inner regions of the rotor takes place here. As a result, the corresponding connecting element on this side may be kept comparatively cool overall, so that a low operating temperature for the continuous current switch arranged thereon and at least for the superconducting parts of the current feeds is enabled. In addition, it may be advantageous to also provide a supply of the coolant on this operating side because the additional mechanical requirements of the axial connecting element are correspondingly lower here.

In an advantageous manner and irrespective of the precise configuration of the switchable conductor section, this may include a conductor length of at least 5 m or at least 20 m. The conductor length may be the “uncoiled” conductor length if the switchable conductor section includes a splittable coil element. Such a long conductor length in the switchable conductor section has the advantage that a high resistance in the normally conducting state and, accordingly, a simple supply of a current to the rotor winding from an external current source is enabled.

The switchable conductor section may have a resistance R_switch of at least 10 MOhm, at least 100 MOhm, or at least 1 Ohm in the normally conducting state in order to enable the supply of current to the rotor winding. In this case, the supply of the current depends on the ratio between the resistance of the normally conducting switchable conductor section and the inductance of the still superconducting remaining part of the rotor winding. In this case, the resistance of the switchable conductor section in its normally conducting state depends on its conductor length, the superconducting material, the conductor geometry, and optionally present further materials which are connected in parallel to the superconducting material in the manner of a shunt resistor.

The self-contained circuit of the rotor winding may advantageously have an inductance L and a resistance R_mode in the fully superconducting state, wherein the ratio L/R_mode is in the range between 50,000 seconds and 500,000 seconds, (e.g., in the range of several hours to several days). This ratio corresponds substantially to the time constant for the decay of the current flowing in the continuous current mode. In this case, the resistance R_mode may refer specifically to the total resistance of the annularly closed circuit which is produced in the fully superconducting operating state.

In a particularly advantageous manner, the rotor winding and/or the switchable conductor section may include a high-temperature superconducting conductor material. High-temperature superconductors (HTS) are superconducting materials with a transition temperature above 25 K and, in the case of some material classes, (e.g., the cuprate superconductors), above 77 K, in which the operating temperature may be achieved by cooling with cryogenic media other than liquid helium. HTS materials are therefore also particularly attractive because these materials may have high upper critical magnetic fields and high critical current densities depending on the operating temperature selected.

The high-temperature superconductor may include magnesium diboride and/or an oxide ceramic superconductor, (e.g., a compound of the type REBa₂CU₃Oₓ (REBCO for short), wherein RE stands for a rare-earth element or a mixture of such elements).

The switchable conductor section may either include the same superconductor material as the rotor winding or a different superconductor material. If different materials are selected, it may be advantageous if the material of the switchable conductor section has a lower transition temperature than the material of the rotor winding. In such an embodiment, the switchable conductor section together with the rotor winding may be cooled by a common cooling system and an opening of the switch may already be achieved at a comparatively low temperature at which, in particular, the rotor winding would still be superconducting.

In this regard, for example, the rotor winding may advantageously include a REBCO material. The switchable conductor section may then either likewise include a REBCO material or it may alternatively include a superconductor with a lower transition temperature, such as magnesium diboride or a high-temperature superconductor of the first generation (for example, a BiSrCaCuO-2212 superconductor). If such a material is selected, thermal switching of the switchable conductor section may be realized in a particularly simple manner.

The self-contained circuit of the rotor winding may have, in particular, a total resistance in the superconducting state in the range below 10 μOhm, or in a range of 1 nOhm and 10 μOhm. Such a low total resistance is advantageous for realizing as loss-free a current flow as possible and for realizing the slowest possible decay of the continuous current (in combination with the inductance of the circuit). Because the continuous current does not have to be absolutely constant, in contrast to magnetic resonance magnets, it may be possible for the total resistance of the closed circuit in the superconducting state to assume a value in a range of 10 μOhm and 500 μOhm, for example. With such high resistances, which may materialize, for example, as a result of contact resistances due to normally conducting connections between individual superconducting coil elements or between the rotor winding and the switchable conductor section and/or within the switchable conductor section, the operation of the electrical machine in the pseudo continuous current mode described in more detail above is also still possible. This may be advantageous for enabling a continuous current mode with comparatively low apparatus costs, in particular with an HTS material, without providing a continuous superconducting material over the entire region of the closed circuit. It is not always possible to provide a superconducting connection with a negligible contact resistance, especially in the case of HTS materials. It is indeed possible, and in some cases advantageous, to obtain a continuously superconducting conductor loop made of HTS material by subsequent splitting of a continuous conductor. This has a favorable effect on the electrical losses but cannot always be managed when producing complex multi-pole rotor windings. It may therefore be favorable to provide a rotor winding with a total resistance above the value to facilitate the production of the winding via the introduction of subsequent contacts.

The rotor winding and the switchable conductor section may be advantageously wound from different superconducting conductors. Alternatively or additionally to selecting different materials as described above, it may be possible for conductors (e.g., strip conductors) to be selected with different widths. In this regard, depending on the existing requirements for the current carrying capacity in the superconducting state and the resistance in the normally conducting state, the conductor in the switchable conductor section may be selected to be either narrower or wider than the conductor in the rotor winding. Alternatively or additionally, the conductor within the switchable conductor section may also differ from the conductor of the rotor winding in terms of optionally present additional layers within the strip conductor stack. In this regard, such a strip conductor, in addition to a carrier substrate and a superconducting layer, may also include one or more normally conducting stabilization layers. These electrical stabilization layers may act as an electrical shunt resistor (a so-called shunt). In particular, the material cross-section of all of the electrical stabilization layers present may be selected to be smaller within the switchable conductor section than within the rotor winding. Such a comparatively low level of electrical stabilization has the advantage that, in the switchable conductor section, a relatively high resistance in the open state may then be achieved with a comparatively short conductor length.

It is also possible, and for a simpler construction sometimes advantageous, if the same conductor is used both in the rotor winding and in the switchable conductor section.

The rotor may have a cooling device with which the rotor winding may be cooled to an operating temperature below the transition temperature of the superconductor material present (both in the rotor winding and in the switchable conductor section). Such a cooling device may include at least one cryostat within which the rotor winding is arranged. In such a cryostat, a fluid coolant may be introduced which cools the superconducting coil elements and conductor sections. The cooling device may include a closed coolant circuit in which such a fluid coolant may circulate. The cryostat may have a vacuum space for better thermal insulation.

According to an embodiment, the rotor may be configured such that the switching of the switchable conductor section to the normally conducting state may be achieved by heating. To this end, the rotor may have a heating element in the vicinity of the switchable conductor section. Alternatively, the switching of the switchable conductor section to the normally conducting state may also be achieved in another manner, for example, by applying a strong magnetic field. To this end, the rotor may be configured such that an additional magnetic field may be incorporated in the vicinity of the switchable conductor section, for example, by introducing a permanent magnet in close proximity to this region, by operating an additional magnetic coil in this region, and/or by introducing a flux-guiding element in this region, which conducts a magnetic flux from another region outside the machine into the region of the continuous current switch.

In a particularly advantageous manner, the switchable conductor section is expediently thermally separated from the rotor winding in such a way that the switchable conductor section may switch to the normally conducting state whilst the rotor winding remains in the superconducting state. This is achieved in particular in that the switchable conductor section is arranged on the first connecting element and is thus spatially separated from the rotor winding. The thermal separation of the rotor winding and the switchable conductor section may be additionally promoted in that the first connecting element is formed form a material whereof the thermal conductivity is comparatively poor. For example, the first connecting element may include a material having a thermal conductivity of only 1 W/m·K or less. In particular, the thermal conductivity of this material may be in a range of 0.1 W/m·K and 1 W/m·K. A material class with which such low thermal conductivities may be achieved is, for example, that of glass fiber reinforced plastics (GFP). Such GFP composites may be used as materials for the axial connecting element, because the GFP composites are able to transit comparatively high torques with a correspondingly low heat input.

The described method may advantageously include the following additional act after the disconnecting of the rotor winding: using the rotor to generate a rotating electromagnetic field in an electrical machine by a continuous current flowing in the rotor winding.

This advantageously enables the machine to be operated without the current source. In this regard, during the operation of the machine, it is possible to omit the weight of the current source and also the weight of a transmission device, which then leads to a correspondingly higher power density of the machine during operation.

In this case, the continuous current may advantageously drop by a maximum amount of 10% over an operating period of three hours. To this end, the rotor may be configured such that the time constant for the drop (e.g., given by L/R) is at least 28.5 hours. If the drop in the continuous current over time has an upper limit, the use of the machine in a vehicle is possible for a period of at least several hours after the disconnection from the current source.

### BRIEF DESCRIPTION OF THE DRAWINGS

The disclosure is described below with the aid of several exemplary embodiments and with reference to the attached drawings, in which:

FIG. 1 depicts a possible embodiment of an electrical machine in a schematic longitudinal section.

FIG. 2 depicts a detailed illustration of the rotor of the machine of FIG. 1.

FIG. 3 depicts an alternative embodiment of a rotor in a schematic longitudinal section.

FIG. 4 depicts an example of a schematic equivalent circuit diagram of a rotor winding with a normally conducting switchable conductor section.

FIG. 5 depicts an example of a corresponding equivalent circuit diagram, in which the switchable conductor section is superconducting.

FIG. 6 depicts an example of a schematic cross-sectional illustration of a bifilar wound switchable coil element 13.

In the figures, identical or functionally identical elements are denoted by the same reference signs.

### DETAILED DESCRIPTION

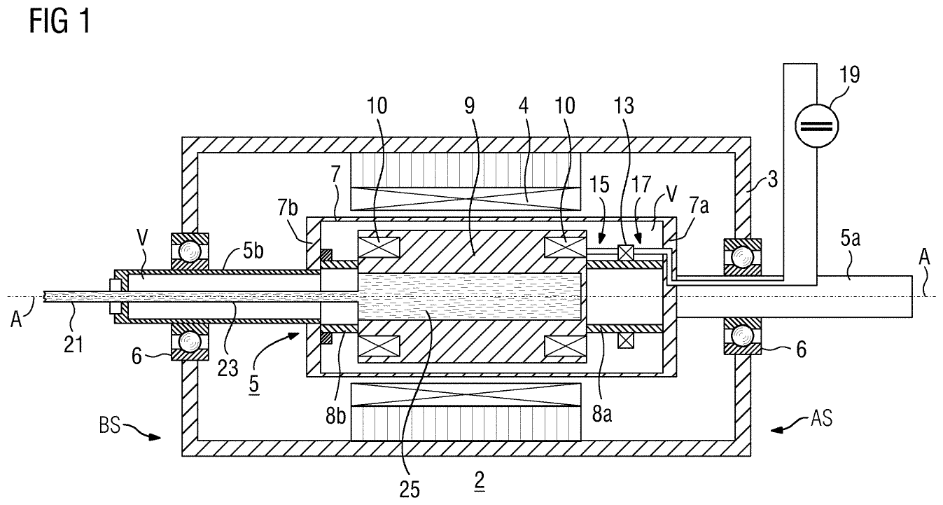

FIG. 1 depicts an electrical machine 2 according to a first exemplary embodiment in a schematic longitudinal section, e.g., along the central machine axis A. The machine 2 includes a stationary machine outer housing 3, which is at room temperature and has a stator winding 4 therein. Within this (for example, evacuable) outer housing and surrounded by the stator winding 4, a rotor 5 is mounted in bearings 6 such that it is rotatable about an axis of rotation A, which rotor includes, on its drive side AS, a solid axial rotor shaft part 5a mounted in the corresponding bearing. The rotor has a rotor outer housing 7 which is configured as a vacuum vessel and in which a winding carrier 9 with a superconducting rotor winding 10 is mounted. Serving this purpose, on the drive side AS, there is a (first) rigid, tubular connecting element 8a between the winding carrier 9 and a disk-shaped side part 7a, fixedly connected to the rotor shaft part 5a, of the rotor outer housing 7. The substantial proportion of the torque transmission also takes place via the rigid connecting element 8a. In an advantageous manner, this connecting device includes a hollow cylinder which has a poor heat conductivity and is made, in particular, of a plastic material reinforced with glass fibers. This material provides a sufficiently high mechanical rigidity and high shear modulus (G modulus) for the torque transmission along with a low heat conductivity. On the operating side, which is opposite the drive side AS and is denoted below by BS, a second connecting element 8b is arranged between the winding carrier 9 and a disk-shaped side part 7b of the rotor outer housing 7.

The superconducting rotor winding 10 may be connected to an external circuit and, in particular, a current source 19 via two parallel-routed current feeds. However, this current source 19 is not a component part of the electrical machine 2, but may instead be disconnected from the machine following the supply of an operating current. The arrangement of the current feeds in FIG. 1 is only represented extremely schematically, in particular, in the region of the rotor shaft part 5a. The only significant aspect is that the current feeds are both arranged in the region of the drive side here and are routed on the first connecting element 8a within the rotor 7. Alternatively to the illustrated variants, the current feeds may also terminate with a plug connection in the region of the element 7a, for example. Cables may then be connected externally here, merely for the current supply act. The current feeds each have a superconducting conductor section 15 and a normally conducting conductor section 17. The superconducting conductor sections 15 are arranged accordingly on the colder axial end of the first connecting element 8a, which faces the cryogenic winding carrier 9. This winding carrier 9 and the superconducting rotor winding 10 arranged thereon are cooled to a cryogenic operating temperature by a cooling system (not illustrated in more detail here). To represent the cooling system, a coolant tube 21, through which a fluid cryogenic coolant 23 may arrive in the region of the rotor 5 which is to be cooled, is shown on the operating side BS of the machine. This fluid coolant therefore circulates in an inner cavity 25 of the rotor. The superconducting rotor winding 10 is thus kept at a cryogenic temperature below the transition temperature of the superconductor material used. The superconducting sections 15 of the current feeds are arranged axially adjacent to this cryogenic region of the rotor. However, as a result of the thermally insulating properties of the first connecting element 8a supporting the current feeds, the operating temperature in this region of the rotor is likewise still below the transition temperature of the superconductor material used for the current feeds 15.

The two superconducting current feeds 15 are electrically connected to a switchable conductor section 13, which is likewise mechanically supported by the first connecting element 8a. This switchable conductor section 13 act as a continuous current switch and enables the supply of a (e.g., pseudo) continuous current to the closed circuit of the superconducting rotor winding 10. The switchable conductor section 13 is at an intermediate temperature, which is above the operating temperature of the superconducting rotor winding but below the warm external ambient temperature. This intermediate temperature may be a temperature in the range of 50 K and 80 K, for example. The temperature of the continuous current switch may be selected such that a sufficiently high critical current density for the continuous current is achieved in the superconducting state of the continuous current switch, but easy thermal switching is still possible in the normally conducting state. In particular, comparatively rapid switching with a low heat input is thus enabled. Axially adjacent to the switchable conductor region 13, this latter is connected to the normally conducting sections 17 of the current feeds. These normally conducting conductor sections 17 are at a somewhat higher temperature level compared to the switchable conductor region 13. Unlike the superconducting conductor sections 15, these normally conducting conductor sections 17 are no longer part of the closed circuit in which the continuous current flows after the power supply process. However, they are required in the open state of the continuous current switch for supplying a current by the external current source 19. In order to be able to transport a sufficiently high supply current, a sufficiently large normally conducting conductor cross-section is necessary here.

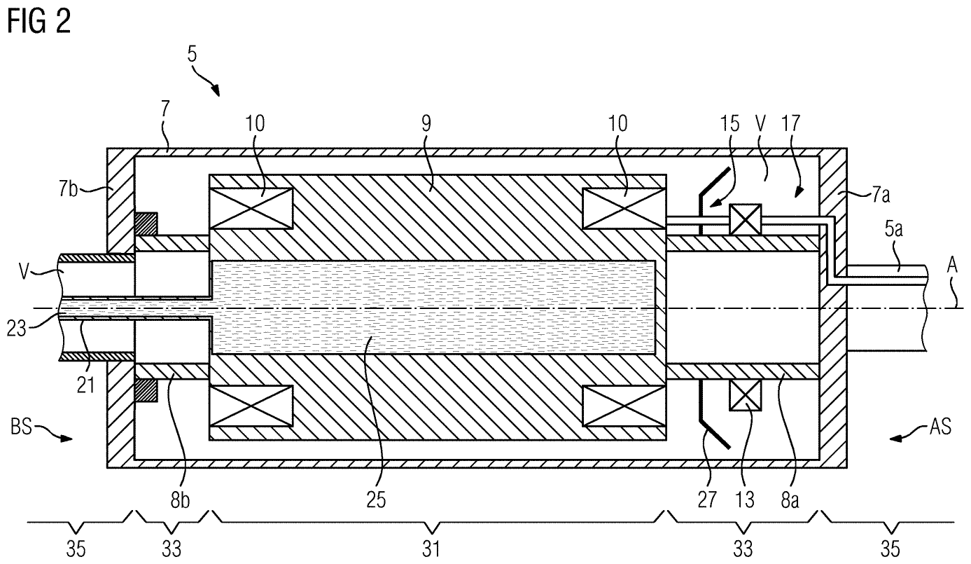

An illustration of a detail of the rotor 5 of the electrical machine of FIG. 1 is shown in FIG. 2. The region shown is essentially that within the rotor outer housing 7 (which may include the two side parts 7a and 7b). In addition to the elements already illustrated in FIG. 1, a radiation shield 27 is further shown here, which is arranged between the switchable conductor section 13 and the rotor winding 10 within the vacuum space V such that heat transfer between these two elements as a result of heat radiation is effectively reduced. Like the other supporting elements of the rotor, this radiation shield 27 is configured to be substantially rotationally symmetrical about the axis of rotation A. The radiation shield 27 is merely interrupted locally by a recess in the region of the of the superconducting current feeds 15. One or more additional radiation shields (not illustrated here) may possibly also be provided, (for example, between the switchable conductor section 13 and the element 7a), which are likewise operated at significantly different temperatures.

The position of the current feeds 15 and 17 is also only illustrated extremely schematically in this figure. In this case, the two current feed paths extending next to one another may be arranged in a common circumferential position on the rotor, as indicated here. However, the current feed paths may also be arranged in an offset circumferential position. In particular, they may also be routed directly on the connecting element and they may also surround this spirally, for example. In any case, the rotational symmetry of the rotor is, at the most, slightly disrupted by the current feed paths. Their mass is comparatively low so that only a slight unbalance of the rotor is generated, which may be easily compensated. However, at least the switchable conductor region is advantageously configured to be rotationally symmetrical so as to thus prevent any further unbalance. In the example shown, the switchable conductor region 13 may be a switchable coil element with a circular cylindrical basic form.

The switchable coil element may be arranged directly on the connecting element 8a, for example, so that this connecting element assumes the function of a winding carrier. This variant is particularly advantageous in the case of a comparatively large external diameter of the connecting element 8a. Alternatively, however, an additional (e.g., advantageously likewise circular cylindrical) winding carrier may be present between the connecting element and the switchable coil element 13.

The elements of the rotor which are radially enclosed by the rotor outer housing 7 are located within a vacuum space V so that they are thermally insulated from the outer wall. In this case, the elements at the coldest temperature level are in the axially inner region, which is represented as the cryogenic region 31 in FIG. 2. The operating temperature in the cryogenic region 31 may be below 50 K, for example, and in particular in the range of 20K and 25K. Adjoining the cryogenic region 31 axially on the right and left are two regions with a moderate temperature, in which the elements enclosed radially by the vacuum space V are at a moderate temperature level. In turn, adjoining these regions axially are two comparatively warm regions 35, in which the two side parts 7a and 7b of the rotor outer housing are arranged. These are at a comparatively warm ambient temperature. The warm regions 35 may be approximately at room temperature, for example.

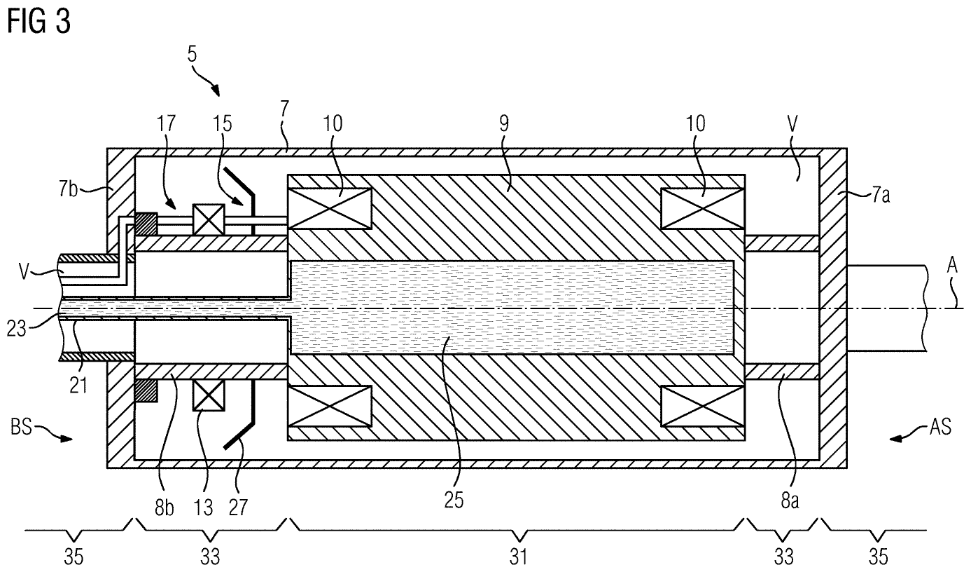

An alternative embodiment of a rotor is shown in a corresponding longitudinal section in FIG. 3. Overall, the rotor 5 is configured similarly to the rotor of FIG. 2 and, in particular, may also be integrated in an electrical machine 2 in a manner similar to the example of FIG. 1. In contrast to the previous example, the switchable conductor section 13 is not arranged on the A side AS here, but on the B side BS of the rotor. This conductor section 13 is also configured as a switchable coil element here, which is mechanically supported accordingly by the B-side second connecting element 8b here. The statements made in connection with the previous example with regard to the moderate temperature level of the switchable conductor region, the rotational symmetry, the heat input, and the radiation shielding apply accordingly in this case.

In the example of FIG. 3, the switchable coil element 13 is located on the side of the rotor on which the fluid coolant 23 is also supplied. This coolant 23 is conducted through a coolant tube 21 in the interior of the second connecting element 8b here. The cooling of this conductor section 13 here, and of the current feeds 15 and 17 likewise arranged on the B side, is additionally facilitated as a result of the spatial proximity of the switchable conductor section 13 to the coolant supply.

Alternatively to the two examples shown here, it is also possible for the coolant supply, together with the current feed and the continuous current switch, to be arranged on the A side. In any case, it is advantageous if the switchable conductor section is arranged on the same axial side as the current feeds, so that it may be easily spatially integrated therewith.

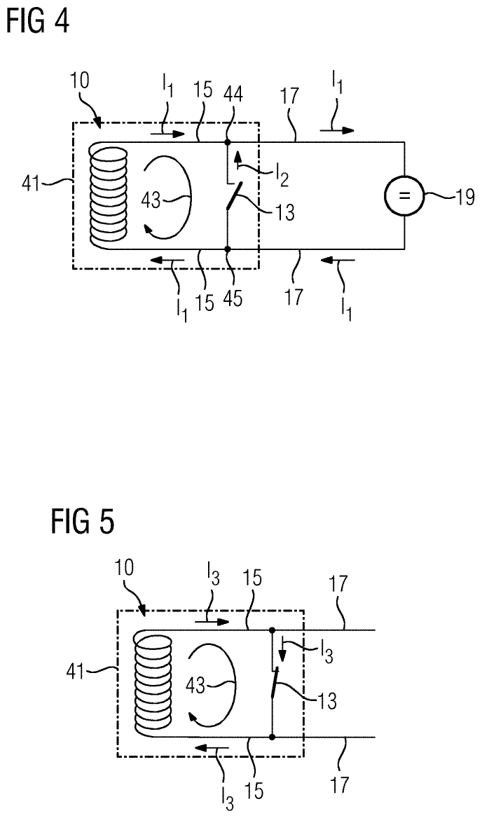

A schematic equivalent circuit diagram of a rotor winding 10 is shown in FIG. 4, which rotor winding is connected to a current source 19 for the current supply. In principle, this may be one of the rotor windings from the two previous exemplary embodiments. The rotor winding 10 is connected to a switchable conductor region 13 via a first connecting node 44 and a second connecting node 45, which conductor region acts as a continuous current switch. The rotor winding 10 here is assembled to form a coil winding (only illustrated very schematically), although, in an actual rotor, it may be structured as a plurality of individual pole coils which are then electrically connected to form a continuous winding. The rotor winding 10 is connected to the switchable conductor region via two superconducting current feeds 15 to form a closed circuit 43 in which a current may flow annularly, at least when the continuous current switch is closed. The conductor elements of this closed circuit 43 are superconducting at operating temperature. They may be surrounded by a common cryostat 41, for example, as indicated here by the dotted line. In this case, however, it should not be ruled out that additional normally conducting contact elements are present between the two individual superconducting conductor elements. As a result of these additional ohmic resistances, a pseudo continuous current mode is possibly achieved rather than a purely continuous current mode.

Adjoining the two connecting nodes 44 and 45 on the right, this circuit may be connected to an external current source 19 via two normally conducting current feeds 17. A direct current may be supplied to the rotor winding 10 as a charging current I₁ via this current source. However, this current source 19 is not a fixed component part of the rotor, but may instead be removed from this during operation and does not contribute to the mass of the rotor.

The switchable conductor section 13 is illustrated schematically in an open configuration in FIG. 4. However, this open configuration is not intended to mean that an electrical connection is not present at all here, but simply that the switchable conductor section is in the normally conducting and not in the superconducting state. Analogously, the closed state of the switch is intended to refer to a superconducting state of the switchable conductor region. The switchable conductor section is therefore a resistor which may be switched between two significantly different values. I₂ here denotes the low leakage current which may flow through the normally conducting switchable conductor region 13 during charging.

FIG. 5 depicts a similar schematic equivalent circuit diagram for the rotor winding 10 and the switchable conductor section 13, which is now in the superconducting state. The external current source 19 has been removed, wherein the disconnection of this connection (as indicated by the remaining conductor sections) may take place outside the cryostat 41 and at the outer end of the two normally conducting current feeds 17. After the disconnection of the current source 19 has taken place, a merely slowly decaying continuous current I₃ now flows through the annularly closed circuit 43. This continuous current flowing over the rotor winding 10 may be used during the operation of an electrical machine including the rotor to generate an exciting field without the current source 19 being part of the electrical machine.

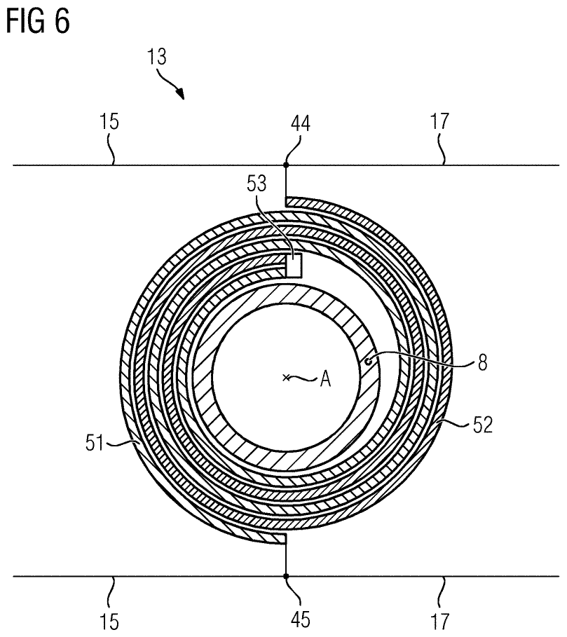

FIG. 6 depicts a schematic cross-sectional illustration (perpendicularly to the axis of rotation A) of a switchable conductor region 13, which is configured as a bifilar wound switchable coil element. This switchable coil element 13 is arranged radially externally on a circular cylindrical connecting element 8, wherein, in principle, this may be an A-side connecting element 8a or a B-side connecting element 8b as in the previous examples. Analogously to the equivalent circuit diagrams of FIGS. 4 and 5, the switchable coil element 13 here is connected to the superconducting current feeds 15 and the normally conducting current feeds 17 in an electrically conductive manner in each case via two connecting nodes 44 and 45.

The switchable coil element 13 itself is wound from a superconducting strip conductor as a bifilar flat coil. This bifilar coil includes two conductor branches 51 and 52, which are routed next to one another in adjacent windings such that their currents flow in mutually opposite directions. Substantial compensation of the inductances of the two conductor branches is realized as a result of this contrary direction of rotation of the current flow within the flat coil winding. On the radially inner side, the two conductor branches are electrically connected via a normally conducting contact element 53. However, in principle, a continuously superconducting conductor may also be present here, which is simply turned around in the interior of the coil.

On the radially outer side of the coil winding, the two conductor branches may either be connected to the current feeds in different circumferential positions (as shown here) or, in principle, in the same circumferential position. The latter embodiment has the advantage that the conductor lengths of the two conductor branches may then be selected to be substantially the same.

Although the disclosure has been described and illustrated more specifically in detail by the exemplary embodiments, the disclosure is not restricted by the disclosed examples and other variations may be derived therefrom by a person skilled in the art without departing from the scope of protection of the disclosure. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

1. A rotor for an electrical machine, the rotor comprising:
a rotor outer housing;
a winding carrier arranged, within the rotor outer housing,
a first axial connecting element, which mechanically connects the winding carrier and the rotor outer housing to one another; and
a superconducting rotor winding configured to form a magnetic field, wherein the superconducting rotor winding is mechanically held by the winding carrier,
wherein the superconducting rotor winding is part of a self-contained circuit within the rotor, in which a continuous current is configured to flow,
wherein the self-contained circuit comprises a continuous current switch having a switchable conductor section configured to be switched between a superconducting state and a normally conducting state, and
wherein the switchable conductor section is arranged on the first axial connecting element.

2. The rotor of claim 1, further comprising:
two current feeds for connecting the superconducting rotor winding to an external circuit,
wherein the two current feeds are arranged at least partially on the first axial connecting element.

3. The rotor of claim 1, wherein the switchable conductor section has at least one switchable coil element.

4. The rotor of claim 3, in wherein the switchable coil element is a bifilar wound coil element.

5. The rotor of claim 1, wherein the first axial connecting element has a tubular design.

6. The rotor of claim 1, wherein the first axial connecting element is arranged on a drive side of the rotor in relation to the winding carrier.

7. The rotor of claim 1, wherein the first axial connecting element is arranged on an operating side of the rotor in relation to the winding carrier.

8. The rotor of claim 1, wherein the switchable conductor section has a resistance of at least 100 MOhm in the normally conducting state.

9. The rotor of claim 1, wherein at least one of the rotor winding or the switchable conductor section comprises a high-temperature superconducting conductor material.

10. The rotor of claim 1, wherein the rotor winding and the switchable conductor section are formed from different superconducting conductors.

11. The rotor of claim 10, wherein the switchable conductor section comprises a superconducting material with a lower transition temperature than a superconducting material of the rotor winding.

12. The rotor of claim 1, wherein the switchable conductor section has a superconducting conductor which has a smaller material cross-section of normally conducting conductor material than the superconducting conductor of the rotor winding.

13. An electrical machine comprising:
a stator; and
a rotor comprising:
a rotor outer housing;
a winding carrier arranged within the rotor outer housing;
an axial connecting element mechanically connecting the winding carrier and the rotor outer housing to one another; and
a superconducting rotor winding configured to form a magnetic field, wherein the superconducting rotor winding is mechanically held by the winding carrier,
wherein the superconducting rotor winding is part of a self-contained circuit within the rotor, in which a continuous current is configured to flow,
wherein the self-contained circuit comprises a continuous current switch having a switchable conductor section configured to be switched between a superconducting state and a normally conducting state, and
wherein the switchable conductor section is arranged on the axial connecting element.

14. A method for operating a rotor, the method comprising:
providing the rotor having a rotor outer housing, a winding carrier arranged within the rotor outer housing, an axial connecting element mechanically connecting the winding carrier and the rotor outer housing, and a superconducting rotor winding mechanically held by the winding carrier, wherein the superconducting rotor winding is part of a self-contained circuit within the rotor, wherein the self-contained circuit comprises a continuous current switch having a switchable conductor section, and wherein the switchable conductor section is arranged on the axial connecting element;
connecting the superconducting rotor winding to an external current source via two connecting nodes arranged within the self-contained circuit, in each case adjacent to the switchable conductor section;
subsequently supplying a current to the superconducting rotor winding by the external current source; and
subsequently disconnecting the superconducting rotor winding from the external current source.

15. The method of claim 14, further comprising:
generating, following the disconnecting of the rotor winding, a rotating electromagnetic field in an electrical machine by a continuous current flowing in the superconducting rotor winding.

16. The rotor of claim 2, wherein the switchable conductor section has at least one switchable coil element.

17. The rotor of claim 16, wherein the switchable coil element is a bifilar wound coil element.

18. The rotor of claim 2, wherein the first axial connecting element has a tubular design.

19. The rotor of claim 2, wherein the first axial connecting element is arranged on a drive side of the rotor in relation to the winding carrier.

20. The rotor of claim 2, wherein the first axial connecting element is arranged on an operating side of the rotor in relation to the winding carrier.
